(19) United States
(12) Patent Application Publication
(10) Pub. No.: US 2011/0146785 A1
(43) Pub. Date: Jun. 23, 2011

(54) PHOTOVOLTAIC DEVICE INCLUDING DOPED LAYER

(75) Inventors: Benyamin Buller, Sylvania, OH (US); Markus Gloeckler, Perrysburg, OH (US); Chungho Lee, Perrysburg, OH (US); Scott McWilliams, Ottawa Hills, OH (US); Rui Shao, Sylvania, OH (US); Zhibo Zhao, Novi, MI (US)

(73) Assignee: First Solar, Inc., Perrysburg, OH (US)

(21) Appl. No.: 12/971,719

(22) Filed: Dec. 17, 2010

Related U.S. Application Data
(60) Provisional application No. 61/287,901, filed on Dec. 18, 2009.
(60) Provisional application No. 61/287,907, filed on Dec. 18, 2009.

(51) Int. Cl. H01L 31/0224; H01L 29/45; H01L 31/18; C23C 14/34

(52) U.S. Cl. 136/256; 257/751; 438/98; 204/298.13; 204/192.1; 257/E29.143; 257/E31.126

(57) ABSTRACT

A photovoltaic cell with a doped buffer layer includes a metal oxide and a dopant.

### CLAIM OF PRIORITY

This application claims priority to U.S. Provisional Patent Application No. 61/287,901, filed on Dec. 18, 2009, which is incorporated by reference in its entirety.

### TECHNICAL FIELD

This invention relates to a photovoltaic cell having a doped layer.

### BACKGROUND

Photovoltaic devices can use transparent thin films that are also conductors of electrical charge. The conductive thin films can include transparent conductive layers that contain one or more transparent conductive oxide (TCO) layers. Past photovoltaic devices can be inefficient at converting solar power into electrical power.

### DESCRIPTION OF DRAWINGS

FIG. 1 is a schematic of a photovoltaic device having a transparent conductive oxide layer, multiple semiconductor layers, and a metal back contact.

FIG. 2 is a schematic of a photovoltaic device having transparent conductive oxide layers, an oxide buffer layer, multiple semiconductor layers, and a metal back contact.

FIG. 3 is a schematic showing a thermal spray process of making a doped sputter target.

FIG. 4 is a process flow chart of making a doped sputter target.

FIG. 5 is a schematic of a sputter target.

FIG. 6 is a schematic showing the reactive sputtering deposition process of the oxide buffer layer.

### DETAILED DESCRIPTION

Photovoltaic devices can include multiple layers formed on a substrate (or superstrate). For example, a photovoltaic device can include a barrier layer, a transparent conductive oxide (TCO) layer, a buffer layer, a semiconductor window layer, and a semiconductor absorber layer, formed in a stack on a substrate. Each layer may in turn include more than one layer or film. For example, the buffer layer can include a first film created (for example, formed or deposited) on the TCO layer and a second film created on the first film. Additionally, each layer can cover all or a portion of the device and/or all or a portion of the layer or substrate underlying the layer. For example, a “layer” can mean any amount of any material that contacts all or a portion of a surface.

A buffer layer can include an oxide buffer layer created (for example, formed or deposited) on top of TCO layers to improve the photovoltaic device performance when the buffer layer has the proper transparency, thickness, and conductivity. The buffer layer can be used to decrease the likelihood of irregularities occurring during the following process, and optimize a junction Fermi level. However, a problem with the oxide buffer layer is maintaining its conductivity in an optimal range. Doping with a dopant can help achieve a good conductivity level in the buffer layer. The doped oxide buffer layer can be formed in any suitable manner, including sputtering from a sputter target including the buffer material and the dopant.

In one aspect, a structure can include a substrate, a barrier layer adjacent to the substrate, a transparent conductive oxide layer adjacent to the barrier layer, and a buffer layer adjacent to the transparent conductive oxide layer. The buffer layer can include a metal oxide doped with a Group V element. The metal oxide can include tin oxide, zinc oxide, or zinc tin oxide. The doping elements can include Group V elements such as antimony, arsenic, vanadium, niobium, or tantalum. The concentration of the Group V element in the buffer layer can be between 10¹⁵ and 10²⁰ atoms/cm³. The concentration of the Group V element in the buffer layer can be between 10¹⁶ and 10¹⁹ atoms/cm³.

The buffer layer can have a uniform equivalent thickness between 100 angstrom and 5000 angstrom. The buffer layer can have a uniform equivalent thickness between 200 angstrom and 2000 angstrom. The buffer layer can have a uniform equivalent thickness between 300 angstrom and 1000 angstrom. The buffer layer can have a uniform equivalent thickness between 500 angstrom and 750 angstrom. The buffer layer can include more than one deposited film. The buffer layer can include multiple layers of doped and undoped layer combinations, or different types and amounts of dopants. The buffer layer can be annealed. The buffer layer can include an oxygen vacancy.

In the structure, the substrate can include soda lime glass or solar float glass. The barrier layer can include silicon oxide, silicon dioxide, silicon aluminum oxide, silicon oxynitride, or silicon aluminum oxynitride. The transparent conductive oxide layer can include fluorine-doped tin oxide, indium tin oxide, cadmium stannate, or zinc aluminum oxide.

In one aspect, a method of manufacturing a structure can include the steps of depositing a barrier layer adjacent to a substrate, depositing a transparent conductive oxide layer adjacent to the barrier layer, and forming a buffer layer adjacent to the transparent conductive oxide layer. The buffer layer can include a metal oxide doped with a Group V element. The metal oxide can include tin oxide, zinc oxide, or zinc tin oxide and the Group V element can include antimony, arsenic, vanadium, niobium, or tantalum. The step of forming a buffer layer adjacent to the transparent conductive oxide layer can include sputtering a sputter target to form the buffer layer. The step of sputtering a sputter target can include sputtering a sputter target including a metal and the Group V element.

The step of sputtering a sputter target can include sputtering the sputter target in an environment including oxygen to control an oxygen vacancy in the buffer layer. The step of forming a buffer layer adjacent to the transparent conductive oxide layer can include physical vapor deposition. The physical vapor deposition can include electron beam evaporation. The step of forming a buffer layer adjacent to the transparent conductive oxide layer can include chemical vapor deposition. The method can include heating the substrate after forming the buffer layer to a temperature between 300 degrees C. and 800 degrees C. The substrate can include heated to a temperature between 400 degrees C. and 700 degrees C. The heating process can be a separate annealing process or a process concurrent with semiconductor depositions. The heating process can be performed in a slightly reducing or oxygen-depleting environment. The method can include the steps of depositing a semiconductor window layer adjacent to the buffer layer, depositing a semiconductor absorber layer adjacent to the semiconductor window layer, and forming a back contact adjacent to the semiconductor absorber layer.

In one aspect, a photovoltaic device can include a substrate, a barrier layer adjacent to the substrate, a transparent conductive oxide layer adjacent to the barrier layer, a buffer layer adjacent to the transparent conductive oxide layer, semiconductor window layer adjacent to the buffer layer, a semiconductor absorber layer adjacent to the semiconductor window layer, and a back contact adjacent to the semiconductor absorber layer. The semiconductor window layer can include cadmium sulfide and the semiconductor absorber layer can include cadmium telluride. The semiconductor absorber layer can include amorphous silicon. The buffer layer can include a metal oxide doped with a Group V element. The metal oxide can include tin oxide, zinc oxide, or zinc tin oxide. The Group V element can include antimony, arsenic, vanadium, niobium, or tantalum. The concentration of the Group V element in the buffer layer can be between 10¹⁵ and 10²⁰ atoms/cm³. The concentration of the Group V element in the buffer layer can be between 10¹⁶ and 10¹⁹ atoms/cm³.

The buffer layer can have a uniform equivalent thickness between 100 angstrom and 5000 angstrom. The buffer layer can have a uniform equivalent thickness between 200 angstrom and 2000 angstrom. The buffer layer can have a uniform equivalent thickness between 300 angstrom and 1000 angstrom. The buffer layer can have a uniform equivalent thickness between 500 angstrom and 750 angstrom. The buffer layer can include more than one deposited film. The buffer layer can be annealed. The buffer layer can include an oxygen vacancy.

In the photovoltaic device, the substrate can include soda lime glass or solar float glass. The barrier layer can include silicon oxide, silicon dioxide, silicon aluminum oxide, silicon oxynitride, or silicon aluminum oxynitride. The transparent conductive oxide layer can include fluorine-doped tin oxide, indium tin oxide, cadmium stannate, or zinc aluminum oxide.

In one aspect, a structure can include a substrate, a barrier layer adjacent to the substrate, a transparent conductive oxide layer adjacent to the barrier layer, and a buffer layer adjacent to the transparent conductive oxide layer. The buffer layer can include a metal oxide doped with an anion. The anion can include a halide ion. The halide ion can include a chloride ion or a fluoride ion. The concentration of the anion in the buffer layer can be between 10¹⁵ and 10²⁰ ions/cm³. The concentration of the anion in the buffer layer can be between 10¹⁶ and 10¹⁹ ions/cm³. The buffer layer can have a uniform equivalent thickness between 200 angstrom and 2000 angstrom.

In the structure, the substrate can include soda lime glass or solar float glass. The barrier layer can include silicon oxide, silicon dioxide, silicon aluminum oxide, silicon oxynitride, or silicon aluminum oxynitride. The transparent conductive oxide layer can include fluorine-doped tin oxide, indium tin oxide, cadmium stannate, or zinc aluminum oxide.

In one aspect, a method of manufacturing a structure can include the steps of depositing a barrier layer adjacent to a substrate, depositing a transparent conductive oxide layer adjacent to the barrier layer, and forming a buffer layer adjacent to the transparent conductive oxide layer. The buffer layer can include a metal oxide doped with an anion. The metal oxide can include tin oxide, zinc oxide, or zinc tin oxide and the anion can include a halide ion. The halide ion can include a fluoride ion or a chloride ion. The step of forming a buffer layer adjacent to the transparent conductive oxide layer can include sputtering a sputter target. The sputter target can be sputtered in a sputter environment including an anion such that the buffer layer includes an oxide of a metal included in the sputter target doped by the anion present in the sputter environment. The sputter target can be sputtered in a sputter environment including a reactive gas species containing a halide ion such as F or Cl. Thus the buffer layer can include an oxide of a metal included in the sputter target, which is doped by the anion present in the sputter environment. The method can include heating the substrate after forming the buffer layer to a temperature between 300 degrees C. and 800 degrees C. The substrate can be heated to a temperature between 400 degrees C. and 700 degrees C. The method can include the steps of depositing a semiconductor window layer adjacent to the buffer layer, depositing a semiconductor absorber layer adjacent to the semiconductor window layer, and forming a back contact adjacent to the semiconductor absorber layer.

In one aspect, a photovoltaic device can include a substrate, a barrier layer adjacent to the substrate, a transparent conductive oxide layer adjacent to the barrier layer, a buffer layer adjacent to the transparent conductive oxide layer, a semiconductor window layer adjacent to the buffer layer, a semiconductor absorber layer adjacent to the semiconductor window layer, and a back contact adjacent to the semiconductor absorber layer. The buffer layer can include a metal oxide doped with an anion. The anion can include a halide ion. The halide ion can include a chloride ion or a fluoride ion. The concentration of the anion in the buffer layer can be between 10¹⁵ and 10²⁰ ions/cm³. The concentration of the anion in the buffer layer can be between 10¹⁶ and 10¹⁹ ions/cm³. The buffer layer can have a uniform equivalent thickness between 200 angstrom and 2000 angstrom.

In the photovoltaic device, the substrate can include soda lime glass or solar float glass. The barrier layer can include silicon oxide, silicon dioxide, silicon aluminum oxide, silicon oxynitride, or silicon aluminum oxynitride. The transparent conductive oxide layer can include fluorine-doped tin oxide, indium tin oxide, cadmium stannate, or zinc aluminum oxide.

A sputter target, including a sputter target used to form the buffer layer described above, can include a sputter material containing a metal and a dopant and a backing tube. The metal can include tin, or zinc, or both. The dopant can include a Group V element, including antimony, arsenic, vanadium, niobium, or tantalum, or any other suitable dopant. The sputter material is connected to the backing tube to form a sputter target. The sputter target can include a dopant concentration between 10¹⁵ and 10²⁰ atoms per cm³ of sputter material, or any other suitable concentration to achieve a dopant concentration in the deposited buffer layer between 10¹⁵ and 10²⁰ atoms per cm³, or 10¹⁵ and 10²⁰ atoms per cm³, or any other suitable dopant concentration. The sputter target can include a bonding layer bonding the sputter material and the backing tube. The backing tube can include stainless steel. The sputter target can be configured to use in reactive sputtering process.

A method of manufacturing a rotary sputter target configured for use in manufacture of photovoltaic device can include forming a sputter material that includes metal and dopant and attaching the sputter material to a backing tube. The metal can include tin, or zinc, or both. The dopant can include a Group V element such as antimony, arsenic, vanadium, niobium, or tantalum, or any other suitable dopant material. The step of forming the sputter target can include a thermal spray forming process. The step of forming the sputter target can include a plasma spray forming process. The step of forming the sputter target can include a powder metallurgy process. The powder metallurgy can include hot press process. The powder metallurgy can include an isostatic process. The step of forming the sputter target can include a flow forming (casting) process. The step of attaching the sputter material to the backing tube can include bonding the sputtering material to the backing tube with a bonding layer.

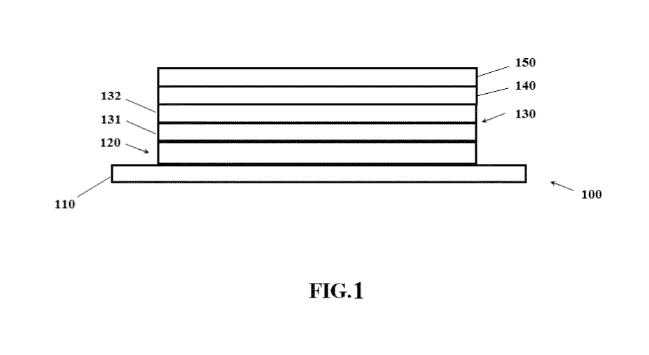

Referring to FIG. 1, photovoltaic device 100 can include transparent conductive oxide layer 120 deposited adjacent to substrate 110. Transparent conductive oxide layer 120 can include a dopant. Transparent conductive oxide layer 120 can be deposited on substrate 110 by reactive sputtering with O₂/Ar gas flow. Transparent conductive oxide layer 120 can be created on substrate 110, for example by forming or depositing TCO layer 120 on substrate 110. Transparent conductive oxide layer 120 can be formed by sputtering, chemical vapor deposition, or any other suitable deposition method. Substrate 110 can include a glass, such as soda-lime glass or solar float glass. Transparent conductive oxide layer 120 can include fluorine-doped SnO2 (SnO₂:F), indium tin oxide (ITO), cadmium stannate (Cd₂SnO₄), zinc aluminum oxide (ZnO:Al) or any suitable material. The thickness of transparent conductive oxide layer 120 can be in the range of about 1000 angstrom to about 5000 angstrom, or any suitable thickness.

A semiconductor layer 130 can be created (for example, formed or deposited) adjacent to transparent conductive oxide layer 120 which can be annealed. Semiconductor layer 130 can include semiconductor window layer 131 and semiconductor absorber layer 132. Semiconductor window layer 131 of semiconductor layer 130 can be deposited adjacent to transparent conductive oxide layer 120. Semiconductor window layer 131 can include any suitable window material, such as cadmium sulfide, and can be deposited by any suitable deposition method, such as sputtering or vapor transport deposition. Semiconductor absorber layer 132 can be deposited adjacent to semiconductor window layer 131. Semiconductor absorber layer 132 can be deposited on semiconductor window layer 131. Semiconductor absorber layer 132 can be any suitable absorber material, such as cadmium telluride, and can be deposited by any suitable method, such as sputtering or vapor transport deposition. Back contact 140 can be deposited adjacent to semiconductor absorber layer 132. Back contact 140 can be deposited adjacent to semiconductor layer 130. Back contact 140 can include any suitable material and can be created by any suitable method. A back support 150 can be positioned adjacent to back contact 140. Back support 150 can include any suitable material. Back support 150 can include soda-lime glass. A photovoltaic device can have a cadmium sulfide (CdS) layer as a semiconductor window layer and a cadmium telluride (CdTe) layer as a semiconductor absorber layer, or amorphous silicon as a semiconductor layer.

A buffer layer can be deposited between the TCO layer and the semiconductor window layer. The buffer layer can be used to decrease the likelihood of irregularities occurring during the formation of the semiconductor window layer. Additionally, a barrier layer can be incorporated between the substrate and the TCO layer. The barrier layer can include any suitable material. The barrier layer can include a silicon oxide. The barrier layer can include silicon dioxide. The barrier layer can include silicon aluminum oxide. The barrier layer can include silicon oxynitride. The barrier layer can include silicon aluminum oxynitride. The barrier layer can have suitable barrier properties. For example, the barrier layer can form a barrier to sodium. The barrier layer can be deposited by any suitable method. The TCO can be part of a three-layer stack, which may include, for example, a silicon dioxide barrier layer, a cadmium tin oxide TCO layer, and a tin oxide buffer layer.

The buffer layer can also include various suitable materials, including zinc tin oxide, zinc oxide, or zinc magnesium oxide.

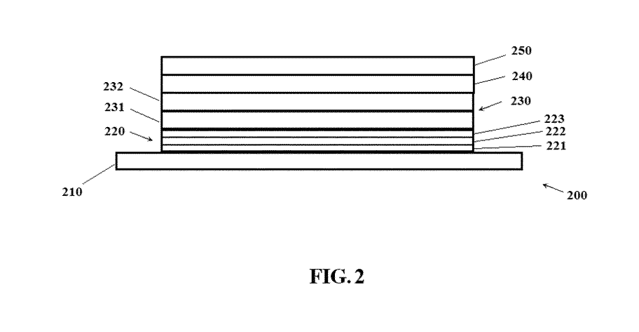

Referring to FIG. 2, photovoltaic device 200 can include TCO stack 220 which can include barrier layer 221, TCO layer 222, and buffer layer 223. These layers can be deposited adjacent to substrate 210. Barrier layer 221 and TCO layer 222 can be deposited on substrate 110 by sputtering, chemical vapor deposition, or any other suitable deposition method. Barrier layer 221 and TCO layer 222 can be deposited on substrate 210 by reactive sputtering with O₂/Ar gas flow. Substrate 210 can include a glass, such as soda-lime glass or solar float glass. Barrier layer 221 can be created (for example, deposited or formed) adjacent to substrate 210. Transparent conductive oxide layer 222 can be created adjacent to barrier layer 221.

The layers in TCO stack 220 (e.g., barrier layer 221, TCO layer 222, and buffer layer 223) can also be manufactured using a variety of deposition techniques, including for example, low pressure chemical vapor deposition, atmospheric pressure chemical vapor deposition, plasma-enhanced chemical vapor deposition, thermal chemical vapor deposition, DC, RF or AC sputtering, spin-on deposition, and spray-pyrolysis. Each deposition layer can be of any suitable thickness in the range of about 1 to about 5000 angstrom. For example, the thicknesses of barrier layer 221, transparent conductive oxide layer 222, and buffer layer 223 can be in the range of about 100 angstrom to about 5000 angstrom respectively. Barrier layer 221 can include silicon oxide, silicon dioxide, silicon aluminum oxide, silicon oxynitride, or silicon aluminum oxynitride, or any other suitable material. Transparent conductive oxide layer 222 can include cadmium stannate (Cd₂SnO₄), fluorine-doped Sn2 (SnO2:F), indium tin oxide (ITO), Zinc aluminum oxide (ZnO:Al), or any other suitable material.

Buffer layer 223 can be deposited or created adjacent to transparent conductive oxide layer. Buffer layer 223 can include any suitable material. Buffer layer 223 can include a metal oxide and a dopant. For example, buffer layer 223 can include, tin oxide (e.g., of formula SnOₓ), zinc oxide (e.g., of formula ZnOₓ), zinc tin oxide (e.g., of formula ZnSnOₓ), or any other suitable buffer material. Examples of dopants that can be included in buffer layer 223 are Group V elements, including antimony, arsenic, vanadium, niobium, tantalum, and any other suitable dopant. Other dopants include suitable anions, including halide ions such as fluoride ions and chloride ions. Buffer layer 223 can include any suitable metal oxide and any suitable dopant and any suitable combination of metal oxide and dopant to achieve a suitable conductivity in buffer layer 223 and improve overall device efficiency. The dopant should be present in a concentration that will also help achieve a working conductivity. For example, buffer layer 223 can have a dopant concentration of 10¹⁵ to 10²⁰ atoms (or ions) of dopant per cm³ of metal oxide. The dopant concentration can be in the range of 10¹⁶ to 10¹⁹ atoms (or ions) of dopant per cm³ of metal oxide. A dopant concentration in this range can result in increased collection efficiency and thus, increased device efficiency of photovoltaic device 200. The doping and thickness of semiconductor window layer 231 including, for example, cadmium sulfide, can also impact the effect of doped buffer layer 223.

Buffer layer 223 can be any suitable thickness. Buffer layer 223 can have a thickness between 100 angstrom and 5000 angstrom, between 200 angstrom and 2000 angstrom, 300 angstrom and 1000 angstrom, or 500 angstrom and 750 angstrom, or any other suitable range or thickness. Buffer layer 223 can itself include more than one layer or film. For example, buffer layer 223 can include a first layer adjacent to TCO layer 222, and having a first dopant concentration and a second layer adjacent to semiconductor window layer 231 and having a second dopant concentration. Different layers having different concentrations can be selected to improve the efficiency of photovoltaic device 200.

Buffer layer 223 can be created adjacent to TCO layer 222 by any suitable method. For example, buffer layer 223 can be created by sputtering a sputter target for form buffer layer 223. Buffer layer 223 can be created by any suitable sputtering process, including AC-, RF-, and DC-pulsed. Buffer layer 223 can be created by physical vapor deposition (for example, electron beam evaporation) or chemical vapor deposition, or any other suitable deposition method. Buffer layer 223 can be reactively sputtered. If buffer layer 223 is sputter-deposited, the sputter target can include a metal which can form a metal oxide as it is deposited on TCO layer 222, and a dopant which can dope the metal oxide. For example, the sputter target can include tin and the Group V element tantalum. During sputtering, tin and tantalum atoms can be ejected from the sputter target. The tin can react with oxygen in the sputter environment to form tin oxide, which can be deposited on TCO layer 222 as buffer layer 223, doped with atoms of tantalum. In some embodiments, buffer layer 223 is doped by including an anion into the sputter environment while sputtering a metal target to form buffer layer 223. For example, a tin target can be sputtered in an environment containing oxygen (to form the metal oxide included in the buffer layer), as well as a reactive gas species containing an anion which can be incorporated into buffer layer 223 as a dopant. The reactive gas species can donate a halide ion such as a fluoride ion or chloride ion, which can then dope the metal oxide buffer layer 223. If buffer layer 223 is prepared by chemical vapor deposition (CVD), the metal precursors can include SnCl₄, Sn(CH₃)₄, Sn(CH₃)₂Cl₂, or

SnCl₃(C₄H₉) as a tin precursor, and Zn(C₂H₅)₂, Zn(CH₃)₂, or Zn(C₅H₇O₂)₂ as a zinc precursor. The dopant can be introduced to control the doping level, such as fluorine, whose precursors can include benzoyl fluoride, hexafluoropropene, hydrogen fluoride, and acetyle fluoride.

Buffer layer 223 can be deposited in an environment including oxygen gas, or argon gas, or both. The amount of oxygen to argon can be controlled to achieve a level of oxygen vacancy in buffer layer 223 that would further contribute to buffer layer 223 having a favorable conductivity to improve the efficiency of photovoltaic device 200. After buffer layer 223 is deposited it can be annealed, which can result in higher doping levels in buffer layer 223 (for example, if the annealing is carried out in a reducing or oxygen-depleting environment). Buffer layer 223 can be annealed after it is deposited on TCO layer 222. Buffer layer 223 can also be annealed during or after the deposition of following layers, such as semiconductor layer 230. Buffer layer 223 can be heated to a temperature between 300 degrees C. and 800 degrees C., or between 400 degrees C. and 700 degrees C., or any other suitable range or temperature.

Semiconductor layer 230 can be created or deposited adjacent to buffer layer 223. Semiconductor layer 230 can include semiconductor window layer 231 and semiconductor absorber layer 232. Semiconductor window layer 231 can include any suitable window material, such as cadmium sulfide, and can be deposited by any suitable deposition method, such as sputtering or vapor transport deposition. Semiconductor absorber layer 232 can be deposited adjacent to semiconductor window layer 231. Semiconductor absorber layer 232 can be deposited on semiconductor window layer 231. Semiconductor absorber layer 232 can be any suitable absorber material, such as cadmium telluride, and can be deposited by any suitable method, such as sputtering or vapor transport deposition. Back contact 240 can be deposited adjacent to semiconductor absorber layer 232. Back contact 240 can be deposited adjacent to semiconductor layer 230. A back support 250 can be positioned adjacent to back contact 240.

The doped rotary sputter targets including a sputter material having metal and dopant (such as a Group V element) can be made by any suitable sputter target manufacture process. The metal and dopant sputter target can be made by spray forming processes (thermal or plasma), or powder metallurgy (hot pressed or isostatic pressed), or by other suitable techniques. The targets can include a sputtering material in connection with a backing material. The sputter material can include metal. The sputter material can include a dopant such as a Group V element. The metal can include tin, zinc, or both, or any other suitable metal. The backing material can include stainless steel. The backing material can include a backing tube. The backing material can include a stainless steel backing tube. The sputter target can include bonding layers applied to the tube surface before application of the metal:dopant sputter material.

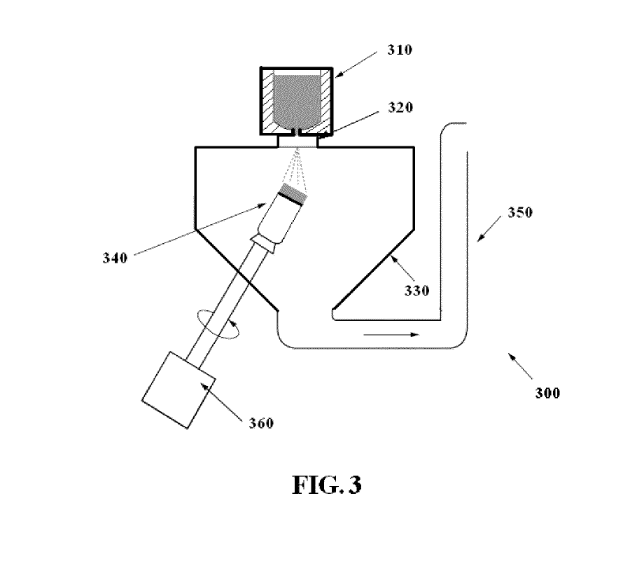

The doped rotary sputter target can be manufactured by spraying a target material onto a base. Metallic target material can be sprayed by any suitable spraying process, including thermal spraying and plasma spraying. The metallic target material can include multiple metals, present in stoichiometrically proper amounts. The base onto which the metallic target material is sprayed can be a tube. Referring to FIG. 3, thermal spray forming process is a method of casting near net shape metal components with homogeneous microstructures via the deposition of semi-solid sprayed droplets onto a shaped substrate. In spray forming system 300, an alloy can be melted in induction furnace 310, then the molten metal with dopant can be slowly poured through a conical tundish into small-bore ceramic nozzle 320. The molten metal exits the furnace as a thin free-falling stream and is broken up into droplets by an annular array of gas jets, and these droplets then proceed downwards into chamber 330, accelerated by the gas jets to impact onto rotary substrate 340. The process can be arranged such that the droplets strike rotary substrate 340 in the semi-solid condition, this can provide sufficient liquid fraction to hold the solid fraction together. Deposition continues, gradually building up a spray formed billet of metal on rotary substrate 340. Spray forming system 300 can further include outlet 350 to exhaust gas. Rotary substrate 340 can be driven by driven unit 360. The resulted pre-form can be porous. In a following step, the pre-from can be consolidated further by Hot Isostatic Pressing (HIP) to 100% density. Spray forming process can have the potential economic benefit to be gained from reducing the number of process steps between melt and finished product. Spray forming can be used to produce strip, tube, ring, clad bar/roll and cylindrical extrusion feed stock products, in each case with a relatively fine-scale microstructure even in large cross-sections.

The doped sputter target can include both a metal (to form a metal oxide buffer layer) and a dopant (to dope the buffer layer). The doped sputter target can have any suitable ratio of dopant to metal. In one embodiment, the ratio of dopant to metal is such that the resulting doped buffer layer has a dopant concentration of 10¹⁵ to 10²⁰ atoms per cm³ of buffer layer material. The doped buffer layer can have a dopant concentration of 10¹⁶ to 10¹⁹ atoms per cm³ of buffer layer material.

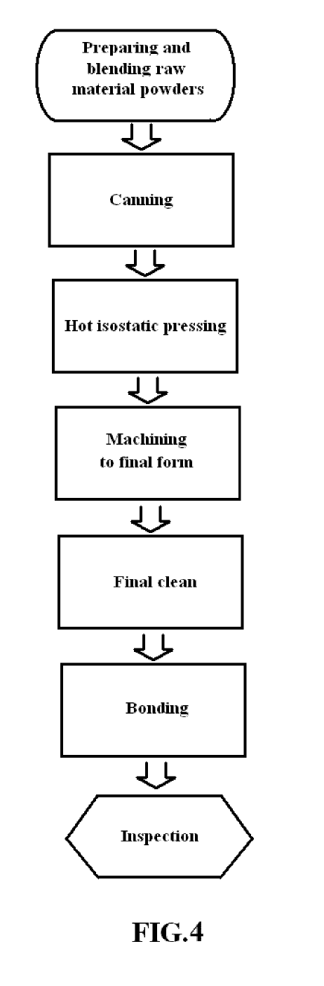

A sputter target can also be manufactured by powder metallurgy. A sputter target can be created by consolidating metallic powder to form the target. The metallic powder can be consolidated in any suitable process (e.g., pressing such as isostatic pressing) and in any suitable shape. The consolidating can occur at any suitable temperature. A sputter target can be formed from metallic powder including more than one metal powder. More than one metallic powder can be present in stoichiometrically proper amounts. Referring to FIG. 4, the process of making a doped sputter target can include the steps of preparing and blending raw material oxide powders, aggregating the powders into a mass (e.g., by canning the powders), hot isostatic pressing the powder mass, machining to final form, final clean, bonding, and inspection. Making a doped sputter target can further include annealing or any other suitable metallurgy technique or other treatment. Powders can include metal powders, such as tin, zinc, or both, and dopant powders, such as Group V elements including antimony, arsenic, vanadium, niobium, or tantalum. In other embodiments, the doped sputter target can also include other suitable dopants. In certain embodiments, the process of making a doped sputter target can further include a pre treatment or post treatment for bonding layers.

A sputter target can also be manufactured by ingot metallurgy. A sputter target can include one or more components of a layer or film to be deposited or otherwise formed on a surface, such as a substrate. For example, a sputter target can include one or more components of an oxide buffer layer to be deposited on top of TCO layers, such as tin for a tin oxide buffer layer or a dopant such as a Group V element such as tantalum. The components can be present in the target in stoichiometrically proper amounts. A sputter target can be manufactured as a single piece in any suitable shape. A sputter target can be a tube. A sputter target can be manufactured by casting a metallic material into any suitable shape, such as a tube. A sputter target can also be manufactured from more than one piece. A sputter target can be manufactured from more than one piece of metal, for example, a piece of tin for a tin oxide buffer layer and a piece of dopant material, such as tantalum. The components can be formed in any suitable shape, such as sleeves, and can be joined or connected in any suitable manner or configuration. One sleeve can be positioned within another sleeve. In certain embodiments, a sputter target can also be manufactured by positioning wire including target material adjacent to a base. For example wire including target material can be wrapped around a base tube. The wire can include multiple metals present in stoichiometrically proper amounts. The base tube can be formed from a material that will not be sputtered. The wire can be pressed (e.g., by isostatic pressing).

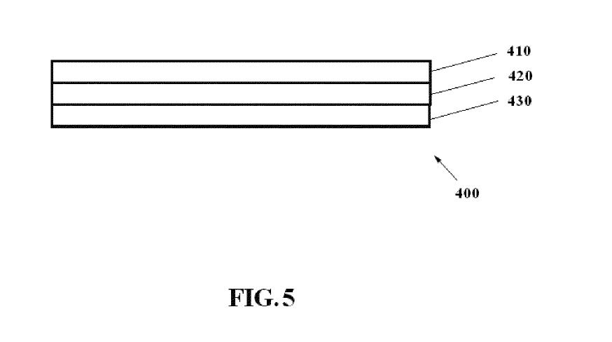

Referring to FIG. 5, doped rotary target 400 can include stainless steel backing tube 430, bonding layer 420, and metal:dopant sputter target material 410. Bonding layer 420 can be applied to tube 430 surface before application of sputter target material 410. Bonding layer 420 can enable a high quality, high melting temperature solder bond between sputter target material 410 and backing tube 430. In certain embodiments, bonding layer 420 can allow the user to increase sputtering rates by 30-100%. Bonding layer 420 can produce a strong, flat, low stress bond that is highly thermally and electrically conductive.

Bonding layer 420 can also include layers of low vapor pressure metals which can be applied to both backing tube 430 and target material 410. Backing tube 430 and target material 410 can then be diffusion bonded together. This bond can provide the necessary mechanical strength required to hold the two materials together. This bond can also provide a high thermally and electrically conductive layer for transfer of heat and electricity from backing tube 430 to target material 410. In addition, the bond can provide a differential slip plane to allow for differences in thermal expansion between the target and the backing plate. This prevents the target from debonding or cracking during the heat up and cool down cycle of the plasma deposition process. A sputter target including metal and dopant sputter material can also be mounted on any suitable backing member (e.g., backing plate). Sputter target material 410 can also be mounted on the backing member by any suitable connector (e.g., a screw, bolt, weld, or adhesive).

Doped rotary target 400 can include a metal (such as tin, or zinc, or both) and a dopant (such as a Group V element, including antimony, arsenic, vanadium, niobium, or tantalum). Doped rotary target 400 can be made from a thermal spray forming, plasma spray forming, powder metallurgy, or flow forming process. The powder metallurgy can include hot press process or isostatic process. Doped rotary target 400 can have any suitable dopant weight percentage to achieve a desired dopant concentration in the buffer layer.

The oxide buffer layer can be deposited by sputtering. In a sputter process, argon plasma can be formed between a substrate and target material and atoms constituting the target material are sputtered out by energetic argon atoms impacting against the sputter target. The sputtered atoms can be deposited on the substrate, forming a thin film on the substrate's surface.

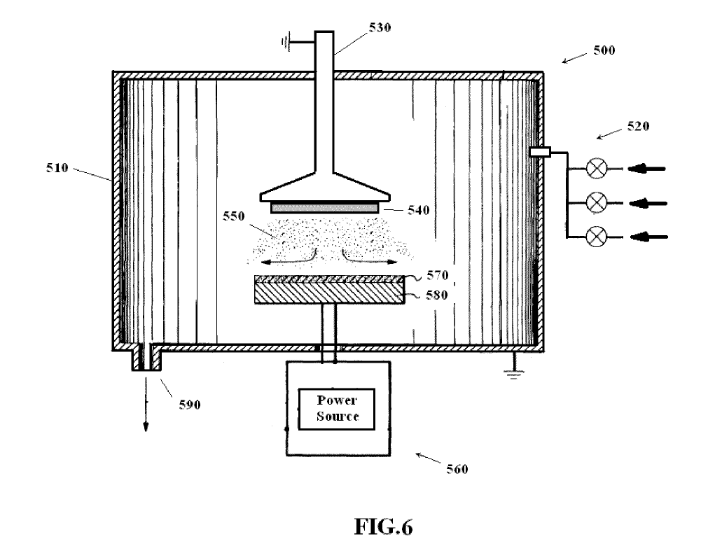

Referring to FIG. 6, sputter system 500 can include chamber 510. Sputter system 500 can be a DC sputtering system and include pulsed DC power supply 560 with a 4 microsecond pulse. The power output of the source can range from about 3 kW (˜1.4 W/cm²) to about 9 kW (˜4.2 W/cm²). The target voltage can range from about 300 volts to about 420 volts. Sputter system 500 can also be a RF sputtering system and include radio-frequency source and matching circuit. Substrate 570 can be mounted on plate 580 or positioned in any other suitable manner. The target-to-substrate distance can range from 50 mm to 500 mm. Grounded rotary fixture 530 can hold doped sputter target 540 facing down. The gas in chamber 510 is taken from inlet 520 with sources of different gas. The gas in chamber 510 can include argon and oxygen. The pressure in chamber 510 can be within the range from about 2.0 mTorr to about 8.0 mTorr. During sputtering process, particles 550 can be deposited from target 540 to substrate 570.

The sputtering process can be a reactive sputtering process. The deposited oxide buffer layer can be created by chemical reaction between the target material and the gas which is introduced into the vacuum chamber. The composition of the film can be controlled by varying the relative pressures or gas flow rates of the inert and reactive gases in chamber 510. For example, the inert gas can be argon and the reactive gas can be oxygen. In other embodiments, the gas in chamber 510 can further include other dopant gas. System 500 can include outlet 590 to exhaust gas. In other embodiments, the sputtering process can be a magnetron sputter deposition, or ion assisted deposition.

A number of embodiments of the invention have been described. Nevertheless, it will be understood that various modifications may be made without departing from the spirit and scope of the invention. It should also be understood that the appended drawings are not necessarily to scale, presenting a somewhat simplified representation of various preferred features illustrative of the basic principles of the invention.

What is claimed is:

1. A structure comprising:
a substrate;
a barrier layer adjacent to the substrate;
a transparent conductive oxide layer adjacent to the barrier layer; and
a buffer layer adjacent to the transparent conductive oxide layer, wherein the buffer layer comprises a metal oxide doped with a Group V element, or doped with an anion.

2. The structure of claim 1, wherein the metal oxide comprises a material selected from the group consisting of tin oxide, zinc oxide, and zinc tin oxide.

3. The structure of claim 1, wherein the Group V element comprises a material selected from the group consisting of antimony, arsenic, vanadium, niobium, and tantalum.

4. The structure of claim 1, wherein the concentration of the Group V element or anion in the buffer layer is between 10¹⁵ and 10²⁰ atoms/cm³.

5. The structure of claim 1, wherein the buffer layer comprises a uniform equivalent thickness between 100 angstrom and 5000 angstrom.

6. The structure of claim 1, wherein the buffer layer comprises more than one deposited film.

7. The structure of claim 1, wherein the buffer layer comprises two layers doped with different Group V elements.

8. The structure of claim 1, wherein the buffer layer is annealed.

9. The structure of claim 1, wherein the buffer layer comprises an oxygen vacancy.

10. The structure of claim 1, wherein the substrate comprises a material selected from the group consisting of soda lime glass and solar float glass; the barrier layer comprises a material selected from the group consisting of silicon oxide, silicon dioxide, silicon aluminum oxide, silicon oxynitride, and silicon aluminum oxynitride; and the transparent conductive oxide layer comprises a material selected from the group consisting of fluorine-doped tin oxide, indium tin oxide, cadmium stannate, and zinc aluminum oxide.

11. The structure of claim 1, wherein the anion comprises a halide ion.

12. The structure of claim 11, wherein the halide ion is selected from the group consisting of a chloride ion and a fluoride ion.

13. A method of manufacturing a structure comprising the steps of:
depositing a barrier layer adjacent to a substrate;
depositing a transparent conductive oxide layer adjacent to the barrier layer; and
forming a buffer layer adjacent to the transparent conductive oxide layer, wherein the buffer layer comprises a metal oxide doped with a Group V element or an anion.

14. The method of claim 13, wherein the step of forming a buffer layer adjacent to the transparent conductive oxide layer comprises sputtering a sputter target to form the buffer layer.

15. The method of claim 14, wherein the step of sputtering a sputter target comprises sputtering a sputter target comprising a metal and the Group V element.

16. The method of claim 14, wherein the step of sputtering a sputter target comprises sputtering the sputter target in an environment comprising oxygen to control an oxygen vacancy in the buffer layer.

17. The method of claim 13, wherein the step of forming a buffer layer adjacent to the transparent conductive oxide layer comprises physical vapor deposition.

18. The method of claim 17, wherein the physical vapor deposition comprises electron beam evaporation.

19. The method of claim 13, wherein the step of forming a buffer layer adjacent to the transparent conductive oxide layer comprises chemical vapor deposition

20. The method of claim 13, further comprising heating the substrate after forming the buffer layer to a temperature between 300 degrees C. and 800 degrees C.

21. The method of claim 13, further comprising the steps of:
depositing a semiconductor window layer adjacent to the buffer layer;
depositing a semiconductor absorber layer adjacent to the semiconductor window layer; and
forming a back contact adjacent to the semiconductor absorber layer.

22. The method of claim 13, wherein the metal oxide is selected from the group consisting of tin oxide, zinc oxide, and zinc tin oxide, and the anion comprises a halide ion.

23. The method of claim 22, wherein the halide ion is selected from the group consisting of a fluoride ion and a chloride ion.

24. A photovoltaic device comprising:
a substrate;
a barrier layer adjacent to the substrate;
a transparent conductive oxide layer adjacent to the barrier layer;
a buffer layer adjacent to the transparent conductive oxide layer, wherein the buffer layer comprises a metal oxide doped with a Group V element;
a semiconductor window layer adjacent to the buffer layer;
a semiconductor absorber layer adjacent to the semiconductor window layer; and
a back contact adjacent to the semiconductor absorber layer.

25. The photovoltaic device of claim 24, wherein the semiconductor window layer comprises cadmium sulfide and the semiconductor absorber layer comprises cadmium telluride.

26. The photovoltaic device of claim 24, wherein the semiconductor absorber layer comprises amorphous silicon.

27. A sputter target comprising:
a sputter material containing a metal and a dopant, wherein the metal is selected from the group consisting of tin and zinc and the dopant is selected from the group consisting of arsenic, antimony, vanadium, niobium, and tantalum; and
a backing tube, wherein the sputter material is connected to the backing tube to form a sputter target.

28. The sputter target of claim 27 comprising a dopant concentration in the sputter material is between 10¹⁵ and 10²⁰ atoms/cm³.

29. The sputter target of claim 27, further comprising a bonding layer bonding the sputter material and the backing tube.

30. The sputter target of claim 29, wherein the backing tube comprises stainless steel.

31. A method of manufacturing a rotary sputter target configured for use in manufacture of photovoltaic device comprising the steps of:
forming a sputter material comprising a metal and a dopant, wherein the metal is selected from the group consisting of tin and zinc and the dopant is selected from the group consisting of arsenic, antimony, vanadium, niobium, and tantalum; and
attaching the sputter material to a backing tube to form a sputter target.
